(19) United States
(12) Patent Application Publication
(10) Pub. No.: US 2008/0237474 A1
(43) Pub. Date: Oct. 2, 2008

(54) SEMICONDUCTOR PHOTODIODE AND METHOD FOR MANUFACTURING SAME, RADIATION DETECTION DEVICE, AND RADIATION IMAGING APPARATUS

(75) Inventors: Junichi TONOTANI, Kanagawa-ken (JP); Hiroshi AIDA, Tochigi-ken (JP); Hiroshi ONIHASHI, Tochigi-ken (JP); Hitoshi CHIYOMA, Tochigi-ken (JP)

Correspondence Address: OBLON, SPIVAK, MCCLELLAND MAIER & NEUSTADT, P.C., 1940 DUKE STREET, ALEXANDRIA, VA, 22314, US

(73) Assignees: KABUSHIKI KAISHA TOSHIBA, Tokyo (JP); TOSHIBA ELECTRON TUBES & DEVICES CO., LTD., Otawara-shi (JP)

(21) Appl. No.: 12/053,930

(22) Filed: Mar. 24, 2008

(30) Foreign Application Priority Data
Mar. 28, 2007 (JP) 2007-084419

(51) Int. Cl. G01T 1/20; H01L 31/105; H01L 31/18

(52) U.S. Cl. 250/363.01; 257/458; 438/98; 257/E31.061

(57) ABSTRACT

A semiconductor photodiode includes: an insulative substrate; a first conductivity type semiconductor layer formed on the insulative substrate; an i-type semiconductor layer formed on the first conductivity type semiconductor layer; a second conductivity type semiconductor layer formed on the i-type semiconductor layer; and a metal electrode. The metal electrode is provided between the insulative substrate and the first conductivity type semiconductor layer so that a peripheral face of the metal electrode is located inside a peripheral face of the first conductivity type semiconductor layer.

### CROSS-REFERENCE TO RELATED APPLICATIONS

This application is based upon and claims the benefit of priority from the prior Japanese Patent Application No. 2007-084419, filed on Mar. 28, 2007; the entire contents of which are incorporated herein by reference.

### BACKGROUND OF THE INVENTION

1. Field of the Invention

This invention relates to a semiconductor photodiode and a method for manufacturing the same, a radiation detection device and a radiation imaging apparatus, and more particularly to a semiconductor photodiode for detecting radiation in a radiation detector for detecting radiation such as X-rays transmitted through a specimen, a method for manufacturing the semiconductor photodiode, a radiation detection device and a radiation imaging apparatus based on the semiconductor photodiode.

2. Background Art

Recently, as a medical X-ray imaging apparatus, instead of the system based on an image intensifier (I.I.), a system based on an X-ray semiconductor planar detector having the potential for higher sensitivity has drawn attention. A semiconductor diode is used as its detection device.

New applications for semiconductor diodes include gene identification in emergency medical care using a portable rapid DNA analyzer combined with an optical interference filter, as well as ambient illuminance sensing and brightness control without using an infrared-cut filter for backlight power saving in mobile phones.

An example of the X-ray imaging apparatus as described above is disclosed in JP-A 11-226001 (Kokai) (1999). In an X-ray semiconductor planar detector, semiconductor detection devices for respective pixels are arranged in a matrix, and each semiconductor detection device uses a thin film transistor (TFT) or other switching device to read light, which has been converted from the X-ray via phosphors, as an electrical signal. The electrical signal from each pixel is sent to an image transmitter and converted into an image. The type of device directly receiving X-rays without the intermediary of phosphors is called the “direct conversion type”, and the type of device converting X-rays into light via phosphors is called the “indirect conversion type”.

A semiconductor detection device of the indirect conversion type includes one TFT and one PIN photodiode (hereinafter abbreviated as PD) for each pixel on a substrate, and the pixels are arranged in two dimensions. The TFT and the PD are formed by thin film semiconductor technologies on a glass substrate covered with SiNₓ or SiO₂, and are covered with a transparent resin protective film. Across the transparent resin above the pixel is formed a phosphor layer for converting incident X-rays into light that can be detected by the PD, and the upper surface of the phosphor layer is provided with a light reflecting film to prevent entrance of light other than X-rays.

When a reverse negative bias is applied to a transparent electrode (ITO electrode) provided on the anode side of the PD, charge is accumulated in a capacitor provided by the capacitance of the PD itself. Upon incidence of light on the PD, the light is absorbed in the i-layer to produce electron-hole pairs, and the electrons and the holes flow in the direction of canceling the accumulated charge. The lower electrode provided between the PD and the substrate is connected to the source electrode of the TFT to drive the TFT, and thereby the amount of lost charge can be read out. This amount of charge is proportional to the intensity of incident X-rays.

Here, the demand for reducing the amount of X-ray exposure to the specimen dictates that the PD used in the X-ray imaging apparatus has high sensitivity and S/N ratio. For higher sensitivity, consideration is given to the transparency of the ITO film, thinning of the p-layer, and the reduction of carrier traps by improving the quality of the p-, i-, and n-layer. For noise reduction, consideration is given to the suppression of circuit noise, TFT noise, and a dark current. Among them, to suppress the dark current, improvement of the film quality and the reduction of an end face leakage current are required.

However, typically in the process for manufacturing a PD, an electrode, an n-layer, an i-layer, a p-layer, and an ITO electrode are laminated in this order on a substrate and subjected to selective etching. In this process, the lower electrode is shattered by sputtering or the like in the final phase of the selective etching and shattered materials are attached to the PD end face. This unfortunately increases the leakage current through the end face and suppresses the S/N ratio.

### SUMMARY OF THE INVENTION

According to an aspect of the invention, there is provided a semiconductor photodiode including: an insulative substrate; a first conductivity type semiconductor layer formed on the insulative substrate; an i-type semiconductor layer formed on the first conductivity type semiconductor layer; a second conductivity type semiconductor layer formed on the i-type semiconductor layer; and a metal electrode provided between the insulative substrate and the first conductivity type semiconductor layer so that a peripheral face of the metal electrode is located inside a peripheral face of the first conductivity type semiconductor layer.

According to another aspect of the invention, there is provided a semiconductor photodiode including: an insulative substrate; a first conductivity type semiconductor layer formed on the insulative substrate; an i-type semiconductor layer formed on the first conductivity type semiconductor layer; a second conductivity type semiconductor layer formed on the i-type semiconductor layer; and a metal electrode provided between the insulative substrate and the first conductivity type semiconductor layer so that a peripheral face of the metal electrode except its signal extraction portion is located inside a peripheral face of the first conductivity type semiconductor layer.

According to another aspect of the invention, there is provided a method for manufacturing a semiconductor photodiode, including: forming a metal film on an insulative substrate; patterning the metal film to form a metal electrode; laminating a first conductivity type semiconductor layer, an i-type semiconductor layer, and a second conductivity type semiconductor layer in this order on the insulative substrate with the metal electrode formed thereon; and selectively etching the semiconductor layers outside a peripheral face of the metal electrode.

According to another aspect of the invention, there is provided a radiation detection device including: a converter configured to convert a radiation into a light having a longer wavelength than that of the radiation; a semiconductor photodiode configured to convert the light into an electrical signal; and a signal processor configured to process the electrical signal, the semiconductor photodiode including: an insulative substrate; a first conductivity type semiconductor layer formed on the insulative substrate; an i-type semiconductor layer formed on the first conductivity type semiconductor layer; a second conductivity type semiconductor layer formed on the i-type semiconductor layer; and a metal electrode provided between the insulative substrate and the first conductivity type semiconductor layer so that a peripheral face of the metal electrode is located inside a peripheral face of the first conductivity type semiconductor layer.

According to another aspect of the invention, there is provided a radiation detection device including: a converter configured to convert a radiation into a light having a longer wavelength than that of the radiation; a semiconductor photodiode configured to convert the light into an electrical signal; and a signal processor configured to process the electrical signal, the semiconductor photodiode including: an insulative substrate; a first conductivity type semiconductor layer formed on the insulative substrate; an i-type semiconductor layer formed on the first conductivity type semiconductor layer; a second conductivity type semiconductor layer formed on the i-type semiconductor layer; and a metal electrode provided between the insulative substrate and the first conductivity type semiconductor layer so that a peripheral face of the metal electrode except its signal extraction portion is located inside a peripheral face of the first conductivity type semiconductor layer.

According to another aspect of the invention, there is provided a radiation imaging apparatus including: a radiation generator configured to emit a radiation; a radiation detection device configured to detect the radiation and to convert the radiation into an electrical signal; and an image transmitter configured to generate an image information based on the electrical signal outputted from the radiation detection device, the radiation detection device including: a converter configured to convert a radiation into a light having a longer wavelength than that of the radiation; a semiconductor photodiode configured to convert the light into an electrical signal; and a signal processor configured to process the electrical signal, the semiconductor photodiode including: an insulative substrate;

a first conductivity type semiconductor layer formed on the insulative substrate; an i-type semiconductor layer formed on the first conductivity type semiconductor layer; a second conductivity type semiconductor layer formed on the i-type semiconductor layer; and a metal electrode provided between the insulative substrate and the first conductivity type semiconductor layer so that a peripheral face of the metal electrode is located inside a peripheral face of the first conductivity type semiconductor layer.

According to another aspect of the invention, there is provided a radiation imaging apparatus including: a radiation generator configured to emit a radiation; a radiation detection device configured to detect the radiation and to convert the radiation into an electrical signal; and an image transmitter configured to generate an image information based on the electrical signal outputted from the radiation detection device, the radiation detection device including: a converter configured to convert a radiation into a light having a longer wavelength than that of the radiation; a semiconductor photodiode configured to convert the light into an electrical signal; and a signal processor configured to process the electrical signal, the semiconductor photodiode including: an insulative substrate;

a first conductivity type semiconductor layer formed on the insulative substrate; an i-type semiconductor layer formed on the first conductivity type semiconductor layer; a second conductivity type semiconductor layer formed on the i-type semiconductor layer; and a metal electrode provided between the insulative substrate and the first conductivity type semiconductor layer so that a peripheral face of the metal electrode except its signal extraction portion is located inside a peripheral face of the first conductivity type semiconductor layer.

### BRIEF DESCRIPTION OF THE DRAWINGS

FIG. 1 is a partial schematic cross-sectional view of a semiconductor photodiode according to the embodiment of the invention;

FIG. 2 is a partial schematic cross-sectional view of a semiconductor photodiode according to a comparative example;

FIG. 3 is a flow chart showing a process for manufacturing a semiconductor photodiode according to the embodiment of the invention;

FIGS. 4A through 4E are process cross-sectional views of a method for manufacturing a semiconductor photodiode of this embodiment;

FIGS. 5A through 5C are process cross-sectional views of the method for manufacturing the semiconductor photodiode of this embodiment;

FIG. 6 shows the bias dependence and temperature dependence of dark current of the semiconductor photodiode according to the embodiment of the invention;

FIG. 7 is a perspective cross-sectional view schematically showing a radiation planar detector in a radiation imaging apparatus according to the embodiment of the invention;

FIG. 8 is a block diagram showing the circuit configuration of the radiation planar detector in the radiation imaging apparatus according to the embodiment of the invention;

FIG. 9 is a schematic cross-sectional view of the main part of a radiation detection device constituting the radiation detector in the radiation imaging apparatus according to a first embodiment of the invention;

FIG. 10 is a plan view of the main part of the radiation detector in the radiation imaging apparatus according to the first embodiment of the invention;

FIG. 11 is a schematic cross-sectional view of the main part of a radiation detection device constituting the radiation detector in the radiation imaging apparatus according to a second embodiment of the invention;

FIG. 12 is a plan view of the main part of the radiation detector in the radiation imaging apparatus according to the second embodiment of the invention;

FIG. 13 is a schematic cross-sectional view of the main part of a radiation detection device constituting the radiation detector in the radiation imaging apparatus according to a third embodiment of the invention; and

FIG. 14 is a block diagram showing the radiation imaging apparatus according to an embodiment of the invention.

### DETAILED DESCRIPTION OF THE INVENTION

An embodiment of the invention will now be described with reference to the drawings.

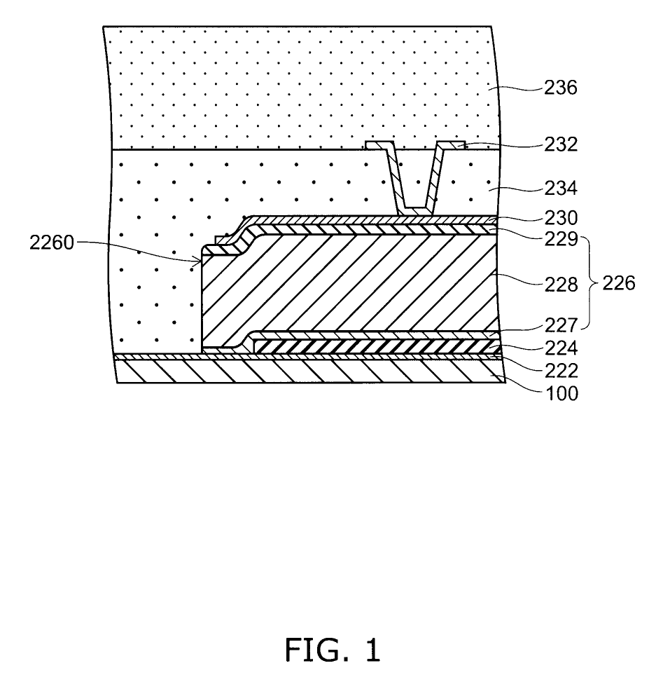

FIG. 1 is a partial schematic cross-sectional view of a semiconductor photodiode according to the embodiment of the invention.

The semiconductor photodiode (hereinafter abbreviated as a-PD) has a structure in which an n-electrode 224, an amorphous silicon (hereinafter abbreviated as a-Si:H) layer 226, and an ITO electrode 230 are laminated on a glass substrate 100 entirely covered with an SiO₂ layer 222 having a thickness of approximately 15 nm, and this laminated structure is buried with a transparent resin 234. Furthermore, a p-electrode 232 is buried in the transparent resin 234, and further buried with a transparent resin 236.

Three types of a-PDs were prepared with its light receiver measuring 150 μm, 500 μm, and 2 mm on a side. A total of 169 a-PDs 150 μm on a side, 16 a-PDs 500 μm on a side, and one a-PD 2 mm on a side were each formed in a square region approximately 2 mm on a side, and ten such units were integrated on a chip measuring 25 mm on a side. Nine such chips were fabricated on a 5-inch glass substrate. Of the above ten units, five units were populated with the a-PD having the structure shown in FIG. 1, and the other five units were populated with the a-PD having the structure shown in a comparative example. Acrylic resin or the like is used as the transparent resin.

The n-electrode 224 is a laminated film of Mo/Al having a thickness of e.g. 50/150 nm. The a-Si:H layer 226 formed thereon covers the peripheral face of the n-electrode 224. The distance between the a-Si:H layer end face 2260 and the peripheral face of the n-electrode 224 is approximately 15 μm.

The a-Si:H layer 226 is composed of an n⁺-type amorphous silicon (hereinafter abbreviated as n⁺-a-Si:H) layer 227, an i-type amorphous silicon (hereinafter abbreviated as i-a-Si: H) layer 228, and a p⁺-type amorphous silicon (hereinafter abbreviated as p⁺-a-Si:H) layer 229 laminated in this order from the n-electrode 224 side, having a thickness of e.g. 10 nm, 1500 nm, and 50 nm, sequentially. The ITO electrode 230 has a thickness of e.g. 70 nm, and the transparent resin 234, 236 has a thickness of e.g. 2.5 μm. The p-electrode 232 has a three-layer structure of Mo/Al/Mo having a thickness of e.g. 50/300/50 nm. The contact width and the line width of the p-electrode 232 and the ITO electrode 230 are e.g. 10 μm and 30 μm, respectively. The structure shown in FIG. 1 is called the a-Si outside structure.

In the a-Si outside structure, when the a-Si:H layer 226 is formed, the n-electrode 224 is enclosed therein. Hence, as described later in detail with reference to the manufacturing method, there is no case where the constituent metals of the otherwise exposed n-electrode 224, Al and Mo, are shattered and attached to the a-Si:H layer end face 2260 by sputtering or the like in the final phase of the selective etching of the a-Si:H layer 226.

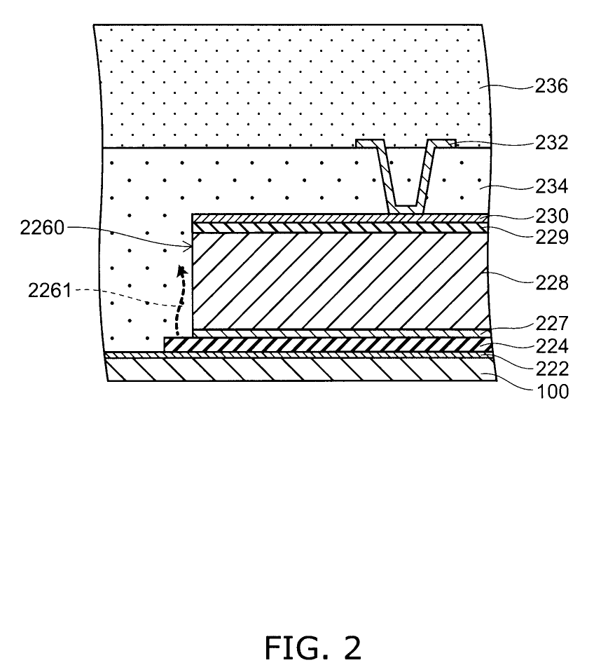

FIG. 2 is a partial schematic cross-sectional view of a semiconductor photodiode according to a comparative example.

In this structure, the peripheral face of the n-electrode 224 is located outside the a-Si:H layer end face 2260. Hence, during the selective etching of the a-Si:H layer 226, the constituent metal of the n-electrode 224, Al or Mo, is shattered and attached to the a-Si:H layer end face 2260, causing an end face leakage current 2261. The structure shown in FIG. 2 is called the a-Si inside structure.

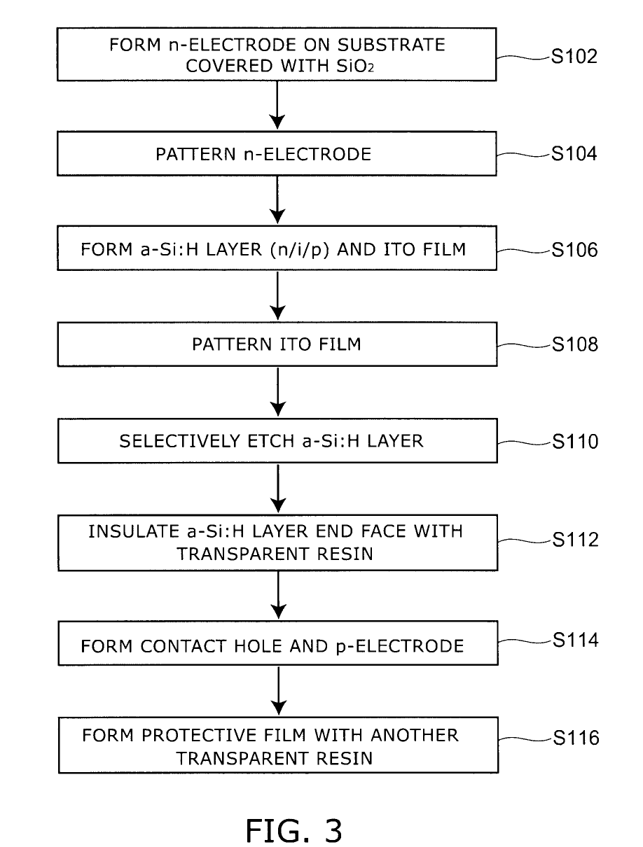

FIG. 3 is a flow chart showing a process for manufacturing an a-PD according to the embodiment of the invention.

More specifically, the process comprises the steps of forming an n-electrode on a substrate covered with SiO₂ (step S102), patterning the n-electrode (step S104), successively forming an a-Si:H layer (n/i/p) and an ITO film (step S106), patterning the ITO film (step S108), selectively etching the a-Si:H layer (step S110), insulating the a-Si:H layer end face with a transparent resin (step S112), forming a contact hole in the transparent resin and forming a p-electrode (step S114), and forming a protective film with another transparent resin (step S116).

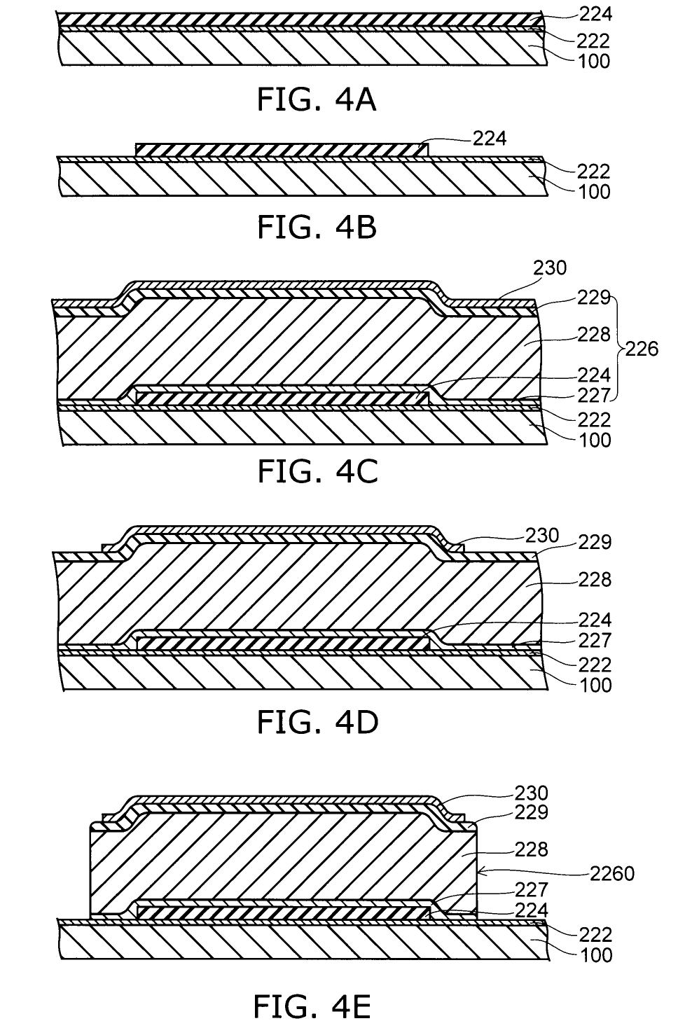

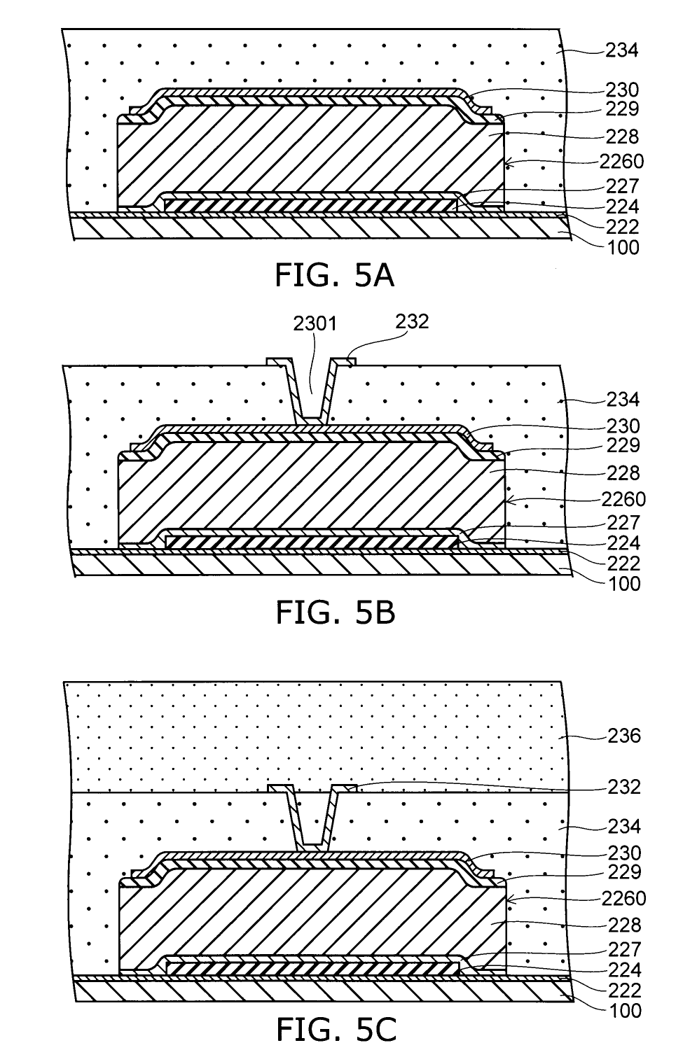

FIGS. 4A to 4H and 5A to 5C are process cross-sectional views of the method for manufacturing an a-PD of this embodiment.

As shown in FIG. 4A, in step S102, a metal film to serve as an n-electrode 224 is formed entirely on a glass substrate 100. Next, as shown in FIG. 4B, in step S104, the n-electrode 224 is patterned. Then, as shown in FIG. 4C, in step S106, an a-Si:H layer 226 is formed by CVD (chemical vapor deposition) to cover the n-electrode 224. This can prevent the n-electrode 224 from being exposed outside the a-Si:H layer 226 and prevent the electrode materials, Al and Mo, from being shattered and attached to the a-Si:H layer end face 2260 during the selective etching of the a-Si:H layer 226. Thus the end face leakage current 2261 can be suppressed.

In the a-Si:H layer 226, the i-a-Si:H layer 228 serves to absorb incident light to produce electron-hole pairs. Hence, preferably, the i-a-Si:H layer 228 has a thickness of 1000 nm or more so as to sufficiently absorb the incident light. In this embodiment, the thickness is set to 1500 nm.

It is preferable that the peripheral face of the n-electrode 224 be located as inside as possible from the a-Si:H layer end face 2260 from the viewpoint of suppressing the end face leakage current 2261. However, consideration should be also given to effectively and steadily capturing electron-hole pairs produced near the a-Si:H layer end face 2260 and converting them into a current from the viewpoint of improving sensitivity. Thus, in this embodiment, the distance between the peripheral face of the n-electrode 224 and the a-Si:H layer end face 2260 is set to approximately 15 μm.

Next, an ITO film is formed by sputtering. As shown in FIG. 4D, in step S108, the ITO film is patterned by etching with aqua regia for defining a light receiver. The mask used for this patterning is also used for selectively etching the a-Si:H layer 226 in the next step S110. Although a different mask may be used, the etching region of the ITO film is then enlarged. Furthermore, as a consequence of side etching of the ITO film, the etching region tends to expand inherently. On the other hand, the area of the ITO film 230 affects the size of the light receiving surface, which in turn affects sensitivity. Hence it is preferable that the same mask as in the etching of the ITO film be used for the selective etching of the a-Si:H layer 226 so as to avoid decreasing the area of the ITO film 230.

As shown in FIG. 4E, the selective etching of the a-Si:H layer 226 in step S110 is performed by RIE (reactive ion etching) with CF₄+SF₆ plasma. Alternatively, etching by a wet process may be also used because the a-Si:H layer 226 has a thickness on the micron order. In this case, contaminants are likely to attach to the a-Si:H layer end face 2260 and also responsible for increasing the end face leakage current 2261, and hence it is preferable to use the a-Si outside structure as the structure of the a-PD.

Next, as shown in FIG. 5A, in step S112, the a-Si:H layer end face 2260 is insulated with a transparent resin 234 to protect the a-PD. As shown in FIG. 5B, in step S114, a contact hole is formed in the transparent resin 234 above the ITO electrode 230, and an interconnect layer of the p-electrode 232 for extracting signals from the ITO electrode 230 is formed. Finally, as shown in FIG. 5C, in step S116, a buried protective layer is formed with another transparent resin 236, and a pad opening (not shown) is formed.

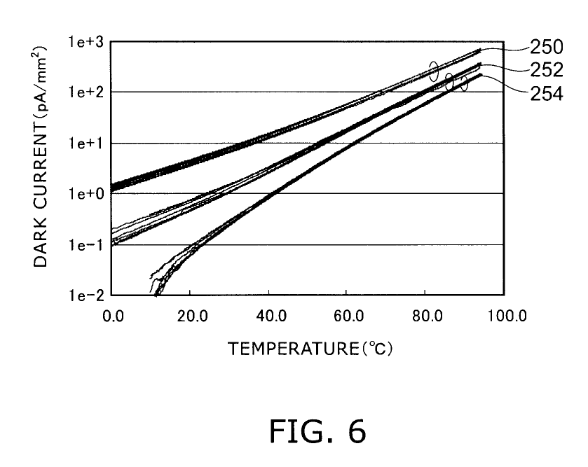

FIG. 6 shows the bias dependence and temperature dependence of dark current of the a-PD according to the embodiment of the invention.

The vertical axis represents the value of dark current per a light receiving area of 1 mm². The dark current was measured in the range of 0° C. to approximately 95° C. in a light-shielded environment. The current was measured using a low-current meter (Keithley 6514) and a constant-voltage source (WAVEFACTORY WF1946). The voltage was increased from a negative bias of 0.2 V to 2.0 V in 0.2 V increments. The positive bias was in the range of 0.2 V to 0.6 V. The dark current was measured at 3 minutes after the voltage was stabilized.

Each set of curves in FIG. 6 shows a series of results obtained for various bias voltages. The set of curves 250 represents dark current in the 169 a-PDs 150 μm on a side having the a-Si inside structure, the set of curves 252 represents dark current in the 169 a-PDs 150 μm on a side having the a-Si outside structure, and the set of curves 254 represents dark current in the one a-PD 2 mm on a side having the a-Si outside structure.

The dark current for the set of curves 250 is larger than the dark current for the set of curves 252. This is presumably because of a larger contribution of the end face leakage current 2261 in the set of curves 250. Around room temperature, the difference is approximately half an order of magnitude. The total light receiving area of the 169 a-PDs 150 μm on a side is 3.8 mm², which is nearly equal to the light receiving area of the one a-PD 2 mm on a side, 4 mm². However, the dark current for the set of curves 252 is larger than the dark current for the set of curves 254. This is presumably because, despite that the total light receiving area is equal, the area of the a-Si:H layer end face 2260 is larger for the a-PDs corresponding to the set of curves 252, making a larger contribution of the end face leakage current 2261 to the dark current.

For these reasons, the a-Si outside structure is preferable for noise reduction of the a-PD.

Other factors responsible for causing leakage current in the a-Si inside structure are also envisioned as follows.

The n-electrode peripheral face located outside the a-Si:H layer end face 2260 may act as a source of carrier emission because of its small distance to the ITO electrode in structure. Furthermore, it is considered that the a-Si:H layer end face 2260 is likely to inherently cause leakage current because it is a cross section of the a-Si.

Also for these reasons, the a-Si outside structure is preferable for noise reduction of the a-PD.

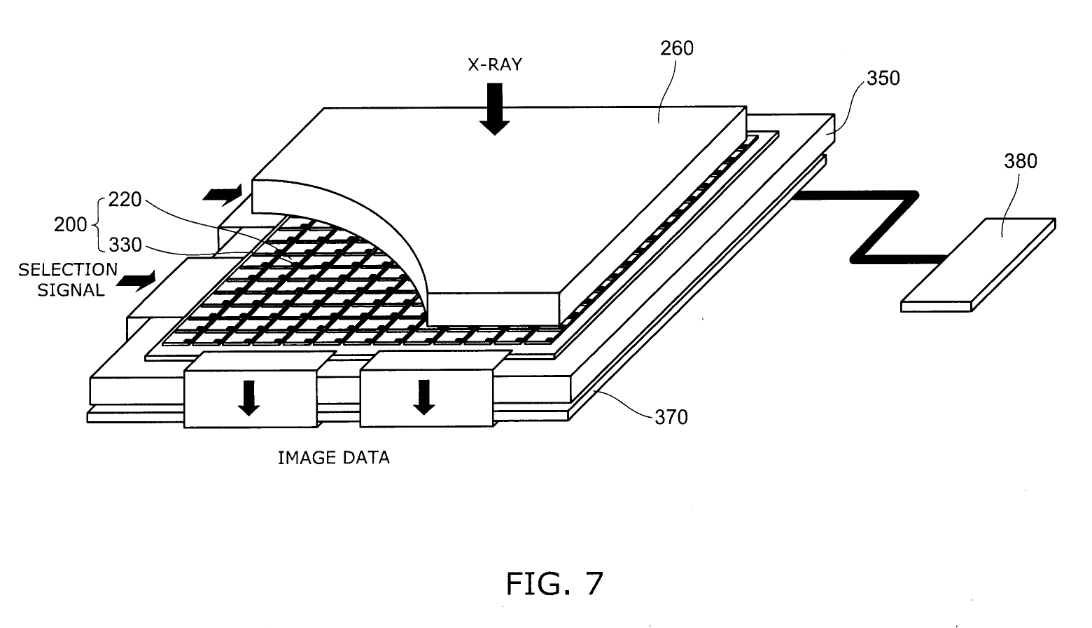

FIG. 7 is a perspective cross-sectional view schematically showing a radiation planar detector in a radiation imaging apparatus according to the embodiment of the invention.

The radiation planar detector comprises a radiation converter 260, a radiation detection device 200 composed of a high-sensitivity low-noise photodiode 220 and a low-noise TFT 330, a base plate 350, a high-speed signal processor 370, and a digital image transmitter 380.

The incident radiation such X-rays are converted into light having a longer wavelength in a high-resolution high-sensitivity CsI scintillator of the radiation converter 260 and converted into an electrical signal in the high-sensitivity low-noise photodiode 220. The electrical signal is then read out for each pixel by the driving of the TFT 330 driven by a selection signal, and is sent as an image data to the high-speed signal processor 370. The data is further processed as image information in the digital image transmitter 380.

In a medical radiation imaging apparatus, the radiation planar detector is adapted to the size of the human body. Hence the radiation planar detector needs to have a considerable size. Therefore a glass substrate is used for the base plate 350 where detection devices are arranged.

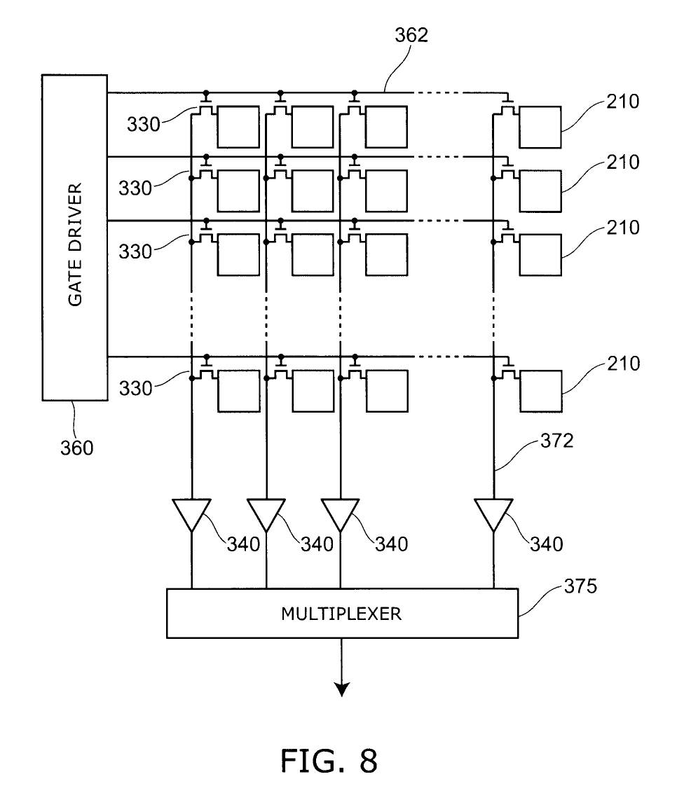

FIG. 8 is a block diagram showing the circuit configuration of the radiation planar detector in the radiation imaging apparatus according to the embodiment of the invention.

The photoelectric converter 210 of the radiation detection device 200, and the TFT 330 for switching between operations such as charge reading from the photoelectric converter 210 and resetting to the state before light incidence are connected to each pixel. Each TFT is supplied with a drive signal from a gate driver 360 commonly connected through a gate drive line 362. The drain of each TFT is commonly connected to a data signal line 372. The data signal line is connected through a low-noise amplifier 340 to a multiplexer 375, which outputs the image data as an imaging signal in time series.

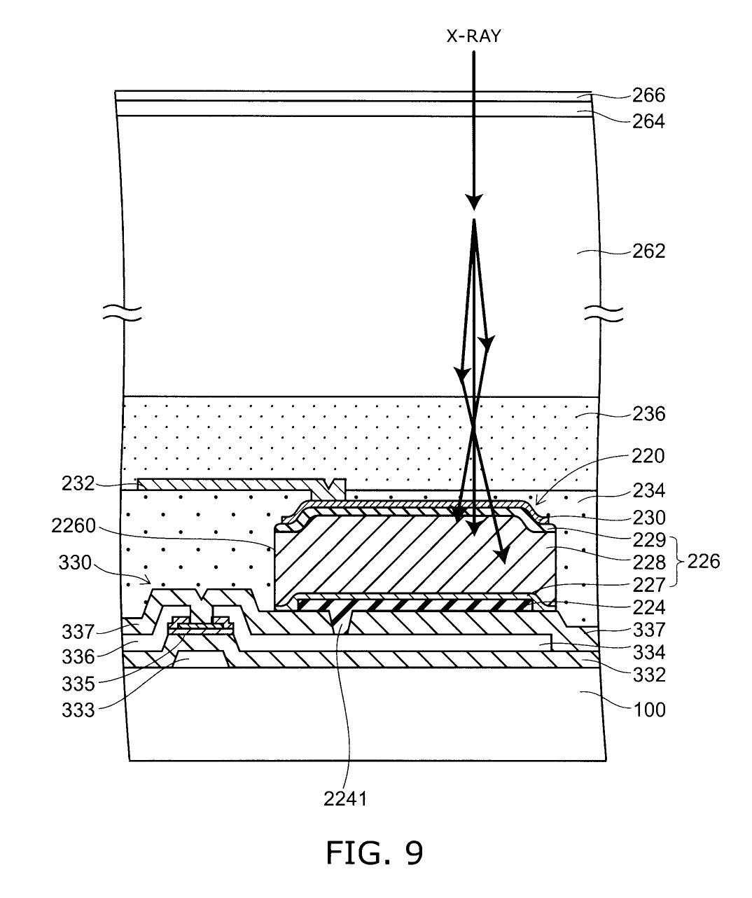

FIG. 9 is a schematic cross-sectional view of the main part of a radiation detection device constituting the radiation detector in the radiation imaging apparatus according to a first embodiment of the invention.

A high-sensitivity low-noise photodiode 220 and a TFT 330 are integrally formed on a glass substrate 100 by semiconductor thin film technologies. The TFT 330 is composed of an insulating layer SiNₓ 332, a gate electrode 333, an a-Si/SiNₓ/n⁺-a-Si structure 335, a source electrode 334, a drain electrode 336, and an insulating layer SiNₓ 337. The SiNₓ layer 332, the source electrode 334, and the insulating layer SiNₓ 337 extend below the high-sensitivity low-noise photodiode 220. Hence, in structure, the high-sensitivity low-noise photodiode 220 is formed on the insulating layer SiNₓ 337 covering the TFT 330.

This embodiment is based on the a-Si outside structure in which the n-electrode 224 for extracting electron-hole pairs produced in the i-a-Si:H layer 228 is located inside the a-Si:H layer end face 2260, and thereby the occurrence of end face current is sufficiently suppressed.

The n-electrode 224 is connected to the source electrode 334 of the TFT through a contact hole 2241 opened in the insulating layer SiNₓ 337.

The electrodes 333, 334, and 336 are made of Al.

In contrast to FIG. 1, the underlayer for the selective etching of the a-Si:H layer 226 is the passivation film of the TFT 330, which is the insulating layer SiNₓ 337 in this embodiment. In RIE of the a-Si film with CF₄+SF₆, it is easy to obtain a selection ratio of e.g. approximately 3 for SiNₓ. Hence selective etching can be performed without damaging the passivation film of the TFT.

A CsI scintillator 262 is provided above the transparent resin 236 with the high-sensitivity low-noise photodiode 220 and the TFT 330 buried therein. The thickness of the CsI scintillator 262 is 600 to 800 μm for sufficiently absorbing radiation such as X-rays. Furthermore, an antireflective film 264 and a moisture-proof film 266 are provided to prevent entrance of light other than radiation such as X-rays.

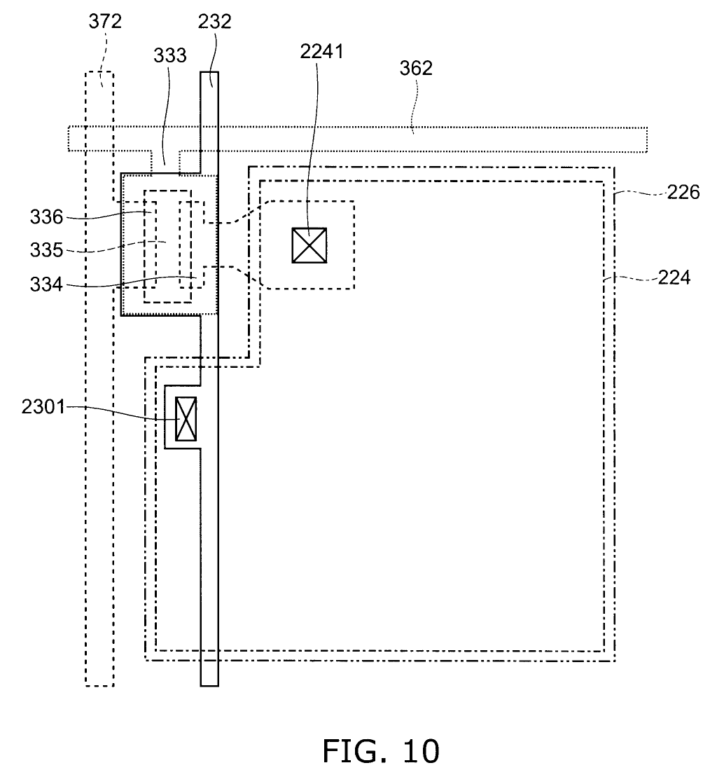

FIG. 10 is a plan view of the main part of the radiation detector in the radiation imaging apparatus according to the first embodiment of the invention.

The contact hole 2241 connecting the n-electrode 224 to the source electrode 334 of the TFT is located below the a-Si:H layer 226. The gate electrode 333 of the TFT is connected to the gate drive line 362, and the drain electrode 336 is connected to the data signal line 372. The p-electrode 232 is connected to the ITO electrode (not shown) 230 on the a-Si:H layer 226 through a contact hole 2301. The p-electrode 232 is extended to above the TFT portion in order to avoid electric field nonuniformity between the p-electrode and the TFT electrode due to the p-electrode being located obliquely above the TFT.

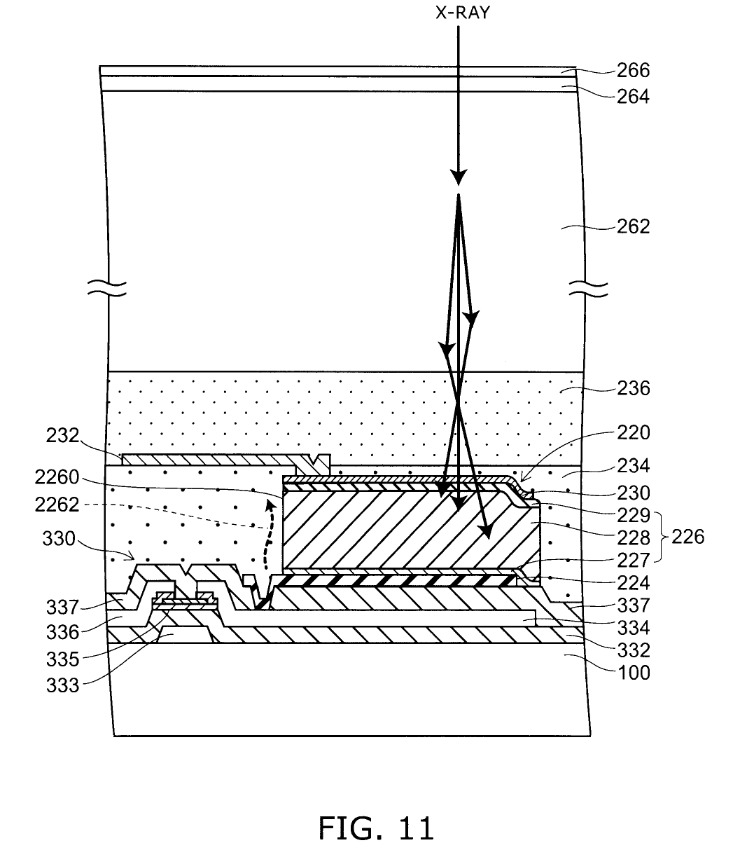

FIG. 11 is a schematic cross-sectional view of the main part of a radiation detection device constituting the radiation detector in the radiation imaging apparatus according to a second embodiment of the invention.

This is different from FIG. 9 in that the contact hole 2241 connecting between the n-electrode 224 and the source electrode 334 is located outside the a-Si:H layer end face 2260. Part of the n-electrode 224 is not covered with the a-Si:H layer 226. Hence its constituent metals, Al and Mo, are shattered by sputtering or the like during the selective etching of the a-Si:H layer 226 and attached to the a-Si:H layer end face 2260, possibly causing an end face current 2262. However, the exposed area of the n-electrode 224 is significantly smaller than that of the a-Si inside structure in which the n-electrode 224 is exposed so as to surround the a-Si:H layer 226. Thus the end face current 2262 is smaller than the end face current 2261 shown in FIG. 2 of the comparative example, and hence does not result in a large dark current.

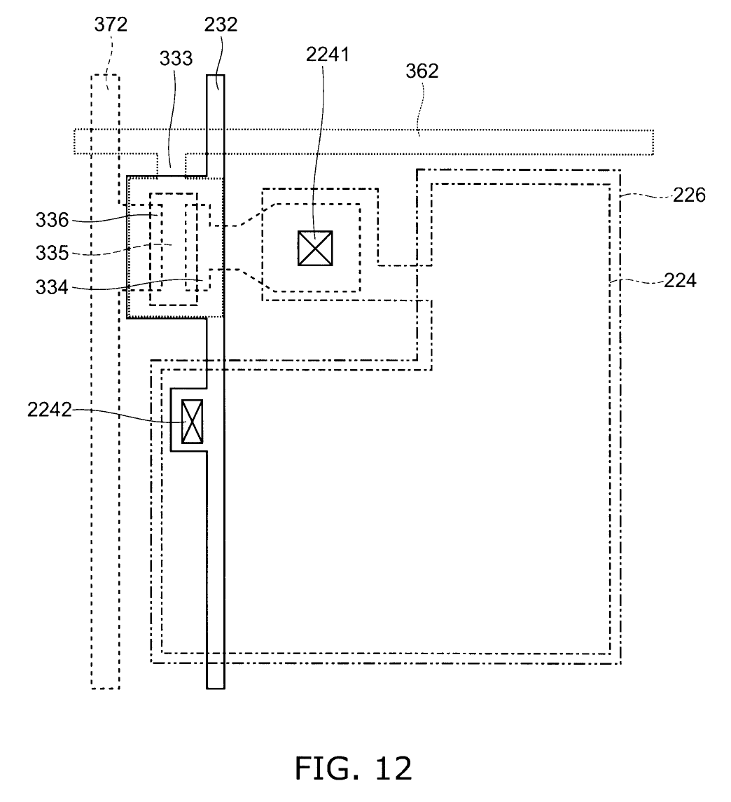

FIG. 12 is a plan view of the main part of the radiation detector in the radiation imaging apparatus according to the second embodiment of the invention.

The contact hole 2241 is located outside the a-Si:H layer 226. However, the exposed area of the n-electrode 224 is small and does not result in a large dark current.

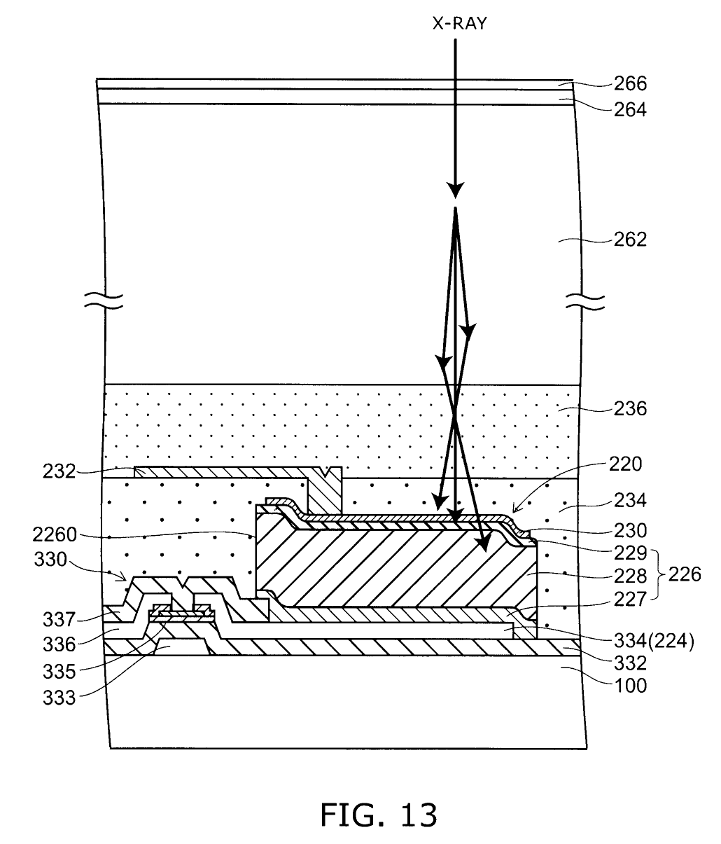

FIG. 13 is a schematic cross-sectional view of the main part of a radiation detection device constituting the radiation detector in the radiation imaging apparatus according to a third embodiment of the invention.

The source electrode 334 of the TFT 330 and the n-electrode 224 of the high-sensitivity low-noise photodiode 220 form an integral structure. That is, the n-electrode 224 of the high-sensitivity low-noise photodiode 220 is commonly formed with the source electrode 334 of the TFT 330. This is different from FIG. 9 in that the TFT 330 and the high-sensitivity low-noise photodiode 220 are provided in the same layer. In this structure, the n-electrode 224 and the source electrode 334 are both covered with the a-Si:H layer 226 or the insulating layer 337.

In TFT fabrication based on semiconductor thin film technologies, the structure with the end face leakage current suppressed can be obtained by forming a source electrode 334 into a configuration also serving as an n-electrode 224, covering the TFT 330 with a passivation film, and then forming an a-Si:H layer 226 followed by selective etching.

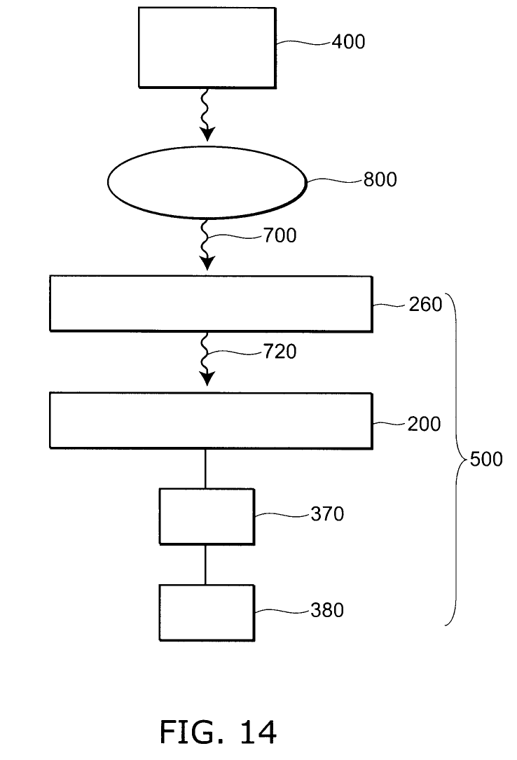

FIG. 14 is a block diagram showing the radiation imaging apparatus according to an embodiment of the invention.

The radiation imaging apparatus includes a radiation generator 400 and a radiation imaging apparatus 500. The radiation 500 includes a radiation converter 260, a radiation detection device 200 composed of a high-sensitivity low-noise photodiode 220 and a low-noise TFT 330, a high-speed signal processor 370, and a digital image transmitter 380. The radiation such as X-rays emitted from the radiation generator 400 penetrates and/or scattered by a subject 800 such as human body. The penetrated and/or scattered radiation 700 is converted into a light 720 having a longer wavelength than the radiation 700. The converted light 720 is converted into an electrical signal in the radiation detection device 200. The electrical signal is then processed in the high-speed signal processor 370, and further processed as image information in the digital image transmitter 380.

The embodiments of the invention have been described with reference to examples. However, the invention is not limited to the above examples, but can be variously modified in practice without departing from the spirit thereof.

For instance, instead of amorphous silicon, various semiconductors including polycrystalline silicon, single crystalline silicon, and semiconductors other than silicon may be used. Further, the above examples are described in the context of application to a medical radiation imaging apparatus. However, the semiconductor photodiode based on semiconductor technologies is also applicable to various small apparatuses. For example, the detector can be directly provided on a semiconductor substrate to configure various portable inspection apparatuses.

1. A semiconductor photodiode comprising:
an insulative substrate;
a first conductivity type semiconductor layer formed on the insulative substrate;
an i-type semiconductor layer formed on the first conductivity type semiconductor layer;
a second conductivity type semiconductor layer formed on the i-type semiconductor layer; and
a metal electrode provided between the insulative substrate and the first conductivity type semiconductor layer so that a peripheral face of the metal electrode is located inside a peripheral face of the first conductivity type semiconductor layer.

2. The semiconductor photodiode according to claim 1, further comprising:
a transparent electrode formed on the second conductivity type semiconductor layer;
a first transparent resin with the transparent electrode and a semiconductor layer including the first conductivity type semiconductor layer, the i-type semiconductor layer and the second conductivity type semiconductor layer buried therein;
a counter electrode in contact with the transparent electrode, the counter electrode buried in the first transparent resin; and
a second transparent resin formed on the first transparent resin.

3. The semiconductor photodiode according to claim 1, wherein
the first conductivity type is n-type, and
the second conductivity type is p-type.

4. A semiconductor photodiode comprising:
an insulative substrate;
a first conductivity type semiconductor layer formed on the insulative substrate;
an i-type semiconductor layer formed on the first conductivity type semiconductor layer;
a second conductivity type semiconductor layer formed on the i-type semiconductor layer; and
a metal electrode provided between the insulative substrate and the first conductivity type semiconductor layer so that a peripheral face of the metal electrode except its signal extraction portion is located inside a peripheral face of the first conductivity type semiconductor layer.

5. The semiconductor photodiode according to claim 4, further comprising:
a transparent electrode formed on the second conductivity type semiconductor layer;
a first transparent resin with the transparent electrode and a semiconductor layer including the first conductivity type semiconductor layer, the i-type semiconductor layer and the second conductivity type semiconductor layer buried therein;
a counter electrode in contact with the transparent electrode, the counter electrode buried in the first transparent resin; and
a second transparent resin formed on the first transparent resin.

6. The semiconductor photodiode according to claim 4, wherein
the first conductivity type is n-type, and
the second conductivity type is p-type.

7. A method for manufacturing a semiconductor photodiode, comprising:
forming a metal film on an insulative substrate;
patterning the metal film to form a metal electrode;
laminating a first conductivity type semiconductor layer, an i-type semiconductor layer, and a second conductivity type semiconductor layer in this order on the insulative substrate with the metal electrode formed thereon; and
selectively etching the semiconductor layers outside a peripheral face of the metal electrode.

8. The method for manufacturing a semiconductor photodiode according to claim 7, further comprising:
forming a transparent electrode on the semiconductor layer; and
patterning the transparent electrode.

9. The method for manufacturing a semiconductor photodiode according to claim 8, wherein a same mask is used in the selectively etching and in the patterning the transparent electrode.

10. The method for manufacturing a semiconductor photodiode according to claim 7, further comprising:
burying the semiconductor layer and the transparent electrode with the first transparent resin;
forming a first opening portion in the first transparent resin and a counter electrode in contact with the transparent electrode therein; and
forming a second transparent resin on the first transparent resin.

11. A radiation detection device comprising:
a converter configured to convert a radiation into a light having a longer wavelength than that of the radiation;
a semiconductor photodiode configured to convert the light into an electrical signal; and
a signal processor configured to process the electrical signal,
the semiconductor photodiode including:
an insulative substrate;
a first conductivity type semiconductor layer formed on the insulative substrate;
an i-type semiconductor layer formed on the first conductivity type semiconductor layer;
a second conductivity type semiconductor layer formed on the i-type semiconductor layer; and
a metal electrode provided between the insulative substrate and the first conductivity type semiconductor layer so that a peripheral face of the metal electrode is located inside a peripheral face of the first conductivity type semiconductor layer.

12. The radiation detection device according to claim 11, further comprising a thin film transistor including a gate electrode, a first insulating layer in contact with the gate electrode, a source electrode, and a second insulating layer covering at least a part of the source electrode, wherein
the thin film transistor and the semiconductor photodiode are integrally formed, and
the first insulating layer, the source electrode and the second insulating layer extend below the semiconductor photodiode.

13. The radiation detection device according to claim 12, wherein the metal electrode of the semiconductor photodiode is connected to the source electrode through a second opening portion provided in the second insulating layer.

14. The radiation detection device according to claim 13, wherein the second opening portion is located below the semiconductor photodiode.

15. A radiation detection device comprising:
a converter configured to convert a radiation into a light having a longer wavelength than that of the radiation;
a semiconductor photodiode configured to convert the light into an electrical signal; and
a signal processor configured to process the electrical signal,
the semiconductor photodiode including:
an insulative substrate;
a first conductivity type semiconductor layer formed on the insulative substrate;
an i-type semiconductor layer formed on the first conductivity type semiconductor layer;
a second conductivity type semiconductor layer formed on the i-type semiconductor layer; and
a metal electrode provided between the insulative substrate and the first conductivity type semiconductor layer so that a peripheral face of the metal electrode except its signal extraction portion is located inside a peripheral face of the first conductivity type semiconductor layer.

16. The radiation detection device according to claim 15, further comprising a thin film transistor including a gate electrode, a first insulating layer in contact with the gate electrode, a source electrode, and a second insulating layer covering at least a part of the source electrode, wherein
the thin film transistor and the semiconductor photodiode are integrally formed, and
the first insulating layer, the source electrode and the second insulating layer extend below the semiconductor photodiode.

17. The radiation detection device according to claim 16, wherein the metal electrode of the semiconductor photodiode is connected to the source electrode through a second opening portion provided in the second insulating layer.

18. The radiation detection device according to claim 17, wherein the second opening portion is located outside a peripheral face of the semiconductor photodiode.

19. A radiation imaging apparatus comprising:
a radiation generator configured to emit a radiation;
a radiation detection device configured to detect the radiation and to convert the radiation into an electrical signal; and
an image transmitter configured to generate an image information based on the electrical signal outputted from the radiation detection device,
the radiation detection device including:
a converter configured to convert a radiation into a light having a longer wavelength than that of the radiation;
a semiconductor photodiode configured to convert the light into an electrical signal; and
a signal processor configured to process the electrical signal,
the semiconductor photodiode including:
an insulative substrate;
a first conductivity type semiconductor layer formed on the insulative substrate;
an i-type semiconductor layer formed on the first conductivity type semiconductor layer;
a second conductivity type semiconductor layer formed on the i-type semiconductor layer; and
a metal electrode provided between the insulative substrate and the first conductivity type semiconductor layer so that a peripheral face of the metal electrode is located inside a peripheral face of the first conductivity type semiconductor layer.

20. A radiation imaging apparatus comprising:
a radiation generator configured to emit a radiation;
a radiation detection device configured to detect the radiation and to convert the radiation into an electrical signal; and
an image transmitter configured to generate an image information based on the electrical signal outputted from the radiation detection device,
the radiation detection device including:
a converter configured to convert a radiation into a light having a longer wavelength than that of the radiation;
a semiconductor photodiode configured to convert the light into an electrical signal; and
a signal processor configured to process the electrical signal,
the semiconductor photodiode including:
an insulative substrate;
a first conductivity type semiconductor layer formed on the insulative substrate;
an i-type semiconductor layer formed on the first conductivity type semiconductor layer;
a second conductivity type semiconductor layer formed on the i-type semiconductor layer; and
a metal electrode provided between the insulative substrate and the first conductivity type semiconductor layer so that a peripheral face of the metal electrode except its signal extraction portion is located inside a peripheral face of the first conductivity type semiconductor layer.
